(19) United States
(12) Patent Application Publication
(10) Pub. No.: US 2026/0107606 A1
(43) Pub. Date: Apr. 16, 2026

(54) CHIP ON CARRIER AND METHOD OF MANUFACTURING THE SAME

(71) Applicant: WAVELORD CO., LTD, Hwaseong-si (KR)

(72) Inventors: Juneo SONG, Suwon-si (KR); Ji Hyung MOON, Gunpo-si (KR); Hyeong Seon YUN, Paju-si (KR); Tae Kyoung KIM, Osan-si (KR)

(73) Assignee: WAVELORD CO., LTD, Hwaseong-si (KR)

(21) Appl. No.: 19/260,514

(22) Filed: Jul. 6, 2025

(30) Foreign Application Priority Data
Oct. 11, 2024 (KR) 10-2024-0138955

(51) Int. Cl. H10H 20/01; H10H 20/857

(52) U.S. Cl. CPC H10H 20/019; H10H 20/032; H10H 20/857

(57) ABSTRACT

The present disclosure relates to a method of manufacturing a chip on carrier, which includes: sequentially forming an undoped semiconductor layer and a light-emitting layer on a growth substrate wafer to manufacture an epitaxy wafer and forming a first ohmic contact electrode on the epitaxy wafer; adhering the first ohmic contact electrode to a temporary substrate wafer through an adhesive layer; removing the growth substrate wafer to expose the undoped semiconductor layer; etching and removing the undoped semiconductor layer to expose the light-emitting layer; forming a second ohmic contact electrode on the light-emitting layer; forming a porous metal layer on the second ohmic contact electrode; bonding the porous metal layer to the support substrate wafer through a bonding layer; and removing the temporary substrate wafer and the adhesive layer.

According to the present disclosure, since a thickness of an element of a vertical chip may be compensated for without lowering the performance or quality of the vertical chip, there is an effect that the vertical chip can be applied to a micro LED display panel using conventional horizontal chip and flip-chip structures.

### CROSS-REFERENCE TO RELATED APPLICATION

This application claims priority to and the benefit of Korean Patent Application No. 2024-0138955, filed on Oct. 11, 2024, the disclosure of which is incorporated herein by reference in its entirety.

### BACKGROUND

### 1. Field of the Invention

The present disclosure relates to a chip on carrier on which a micro light-emitting diode (LED) chip element for a micro LED display is formed and a method of manufacturing the same, and more specifically, to a chip on carrier capable of compensating for a thickness of an element of a vertical chip so that a micro LED chip element with a vertical chip structure may be applied to a panel for a micro LED chip element with conventional horizontal chip and flip-chip structures and process, and a method of manufacturing the same.

### 2. Discussion of Related Art

Generally, an epitaxy structure for manufacturing a gallium nitride (GaN)-based micro light-emitting diode (LED) chip element has a form in which an unGaN layer (an undoped GaN layer) which is an undoped semiconductor layer on a sapphire growth substrate wafer, an nGaN layer (an n-type GaN layer) which supplies electrons to an active region, a multi quantum well layer (an MQW layer) which is the active region, a p-type electron blocking layer (a pEBL) for reducing leakage of carrier electrons to the outside of the active region, and a pGaN layer (a p-type GaN layer) which supplies holes to the active region are sequentially stacked, and in this case, since the unGaN layer typically has a thickness of about 2.5 to 3 μm, the nGaN layer has a thickness of about 2 to 2.5 μm, the MQW layer has a thickness of about 50 nm, the EBL has a thickness of about 10 to 50 nm, and the pGaN layer has a thickness of about 200 to 500 nm, the entire micro LED epitaxy structure may have a thickness in a range of about 5 to 7 μm.

Currently, micro LED chips are mainly manufactured in the form of a horizontal chip or flip chip using the micro LED epitaxy structure, but in the horizontal chip or flip chip, since p-type and n-type ohmic contact electrodes are formed on the same surface through mesa etching or the like, issues such as difficulty in reducing a chip size, micro cracks in a panel transfer process, and the like are present, and simultaneously, a relatively thick unGaN layer is used as is without removing.

It is preferable that an element is manufactured in a vertical chip form to further reduce the size and thickness of micro LED chip element in the future. This is because, due to the characteristics of a vertical chip in which p-type and n-type ohmic contact electrodes are formed on different surfaces, the nGaN layer should be necessarily exposed by removing the unGaN layer with a thickness of 3 to 3.5 μm to form the n-type ohmic contact electrode, there is an advantage in easily reducing the thickness of the chip. Furthermore, the vertical chip exhibits excellent advantages at high current, and has excellent characteristics in terms of optical efficiency, high output, operating voltage reduction, thermal characteristics, and the like.

Meanwhile, a panel and subsequent processes to which conventional micro LED chip elements are transferred are optimized for the thicknesses of the horizontal chip and the flip chip in which the unGaN layer is not removed. When the above-described vertical chip is transferred to the conventional panel, a step is generated by a thickness of the removed unGaN layer and thus causes difficulty in subsequent processes, and there is a problem that it is difficult to manufacture normal products.

Further, in order to compensate for the thickness in the vertical chip, there is a method of growing the nGaN layer instead of the unGaN layer by doping silicon (Si), germanium (Ge), or the like from the beginning when the GaN layer is grown on an initial sapphire growth substrate, but in this case, the film quality of the nGaN layer is poor due to the characteristics of the nGaN layer, and the quality of other semiconductor layers which are subsequently grown also deteriorates, and thus a problem such as a reduced light amount occurs.

Accordingly, a method capable of compensating for a thickness of an element of the vertical chip without lowering the quality of the vertical chip so that the vertical chip may be applied to panels for conventional horizontal chip and flip-chip structures is required.

(Patent Document 0001) Korean Registered Patent No. 10-1285527

### SUMMARY OF THE INVENTION

The present disclosure is directed to solving the above-described problems in the related art, and is directed to providing a chip on carrier capable of compensating for a thickness of an element of a vertical chip so that a vertical chip structure may be applied to panels for conventional horizontal chip and flip-chip structures and a method of manufacturing the same.

According to the present disclosure, the above object is achieved by a method of manufacturing a chip on carrier including: sequentially forming an undoped semiconductor layer and a light-emitting layer on a growth substrate wafer to manufacture an epitaxy wafer and forming a first ohmic contact electrode on the epitaxy wafer; adhering the first ohmic contact electrode to a temporary substrate wafer through an adhesive layer; removing the growth substrate wafer to expose the undoped semiconductor layer; etching and removing the undoped semiconductor layer to expose the light-emitting layer; forming a second ohmic contact electrode on the light-emitting; forming a porous metal layer a layer on the second ohmic contact electrode; bonding the porous metal layer to the support substrate wafer through a bonding layer; and removing the temporary substrate wafer and the adhesive layer.

Further, the porous metal layer may be formed of nano porous gold (NPG).

In addition, the light-emitting layer may include an n-type semiconductor layer, an active layer, and a p-type semiconductor layer.

In addition, the support substrate wafer may be formed of sapphire.

According to the present disclosure, the above object is achieved by a chip on carrier including: a support substrate wafer; a bonding layer formed on the support substrate wafer; a porous metal layer formed on the bonding layer; a second ohmic contact electrode formed on the porous metal layer; a light-emitting layer formed on the second ohmic contact electrode; and a first ohmic contact electrode formed on the light-emitting layer.

According to the present disclosure, the above object is achieved by a method of manufacturing a chip on carrier including: sequentially forming an undoped semiconductor layer and a light-emitting layer on a growth substrate wafer to manufacture an epitaxy wafer and forming a first ohmic contact electrode on the epitaxy wafer; forming a porous metal layer on the first ohmic contact electrode; adhering the porous metal layer to a temporary substrate wafer through an adhesive layer; removing the growth substrate wafer to expose the undoped semiconductor layer; etching and removing the undoped semiconductor layer to expose the light-emitting layer; forming a second ohmic contact electrode on the light-emitting layer; bonding the second ohmic contact electrode to the support substrate wafer through a bonding layer; and removing the temporary substrate wafer and the adhesive layer.

Further, the porous metal layer may be formed of nano porous gold (NPG).

In addition, the light-emitting layer may include an n-type semiconductor layer, an active layer, and a p-type semiconductor layer.

In addition, the support substrate wafer may be formed of sapphire.

According to the present disclosure, the above object is achieved by a chip on carrier including: a support substrate wafer; a bonding layer formed on the support substrate wafer; a second ohmic contact electrode formed on the bonding layer; a light-emitting layer formed on the second ohmic contact electrode; a first ohmic contact electrode formed on the light-emitting layer; and a porous metal layer formed on the first ohmic contact electrode

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a flowchart of a method of manufacturing a chip on carrier according to a first embodiment of the present disclosure;

FIG. 2 shows a process of manufacturing the chip on carrier according to the method of manufacturing the chip on carrier according to the first embodiment of the present disclosure;

FIG. 3 shows the chip on carrier according to the first embodiment of the present disclosure in its entirety;

FIG. 4 is a flowchart of a method of manufacturing a chip on carrier according to a second embodiment of the present disclosure;

FIG. 5 shows a process of manufacturing the chip on carrier according to the method of manufacturing the chip on carrier according to the second embodiment of the present disclosure; and

FIG. 6 shows the chip on carrier according to the second embodiment of the present disclosure in its entirety.

### DETAILED DESCRIPTION OF EXEMPLARY EMBODIMENTS

Hereinafter, some embodiments of the present disclosure will be described in detail with reference to exemplary drawings. In adding reference numerals to components of each drawing, it should be noted that the same components have the same numerals as much as possible even when represented in different drawings.

Further, in describing the embodiments of the present disclosure, when it is determined that the specific description of a related known configuration or function interferes with the understanding of the embodiments of the present disclosure, the detailed description thereof will be omitted.

In addition, in describing the components of the present disclosure, the terms such as first, second, A, B, (a), and (b) may be used. These terms are only for the purpose of distinguishing one component from another component, and the nature, sequence, order, or the like of the corresponding components is not limited by these terms.

Further, in the present disclosure, a chip on carrier means that a micro light-emitting diode (LED) chip element is formed on a carrier substrate to easily transfer the micro LED chip element to a micro LED display panel, and the carrier substrate may be a circular wafer (made of sapphire, Si, glass, an organic material, or the like) or a rectangular substrate cut to a preset standard.

In addition, in the terms of a growth substrate wafer, a temporary substrate wafer, and a support substrate wafer in the present disclosure, the term ‘wafer’ may be omitted, and the term ‘wafer’ may be used interchangeably with the term ‘carrier.’ For example, in the chip on carrier of the present disclosure and a method of manufacturing the same, the support substrate wafer may mean a support substrate carrier.

Hereinafter, a method S100 of manufacturing a chip on carrier according to a first embodiment of the present disclosure will be described in detail with reference to the attached drawings.

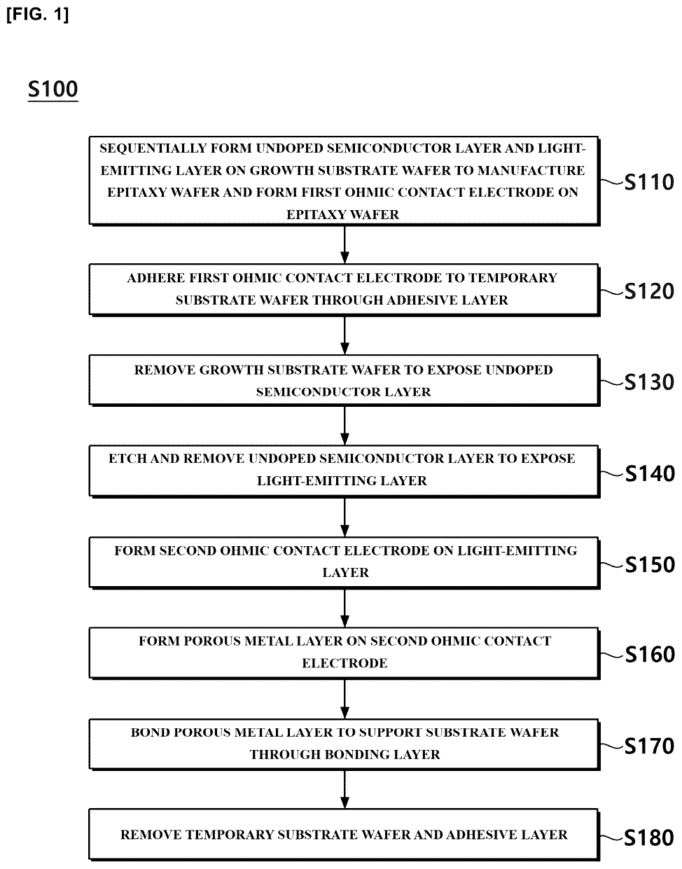

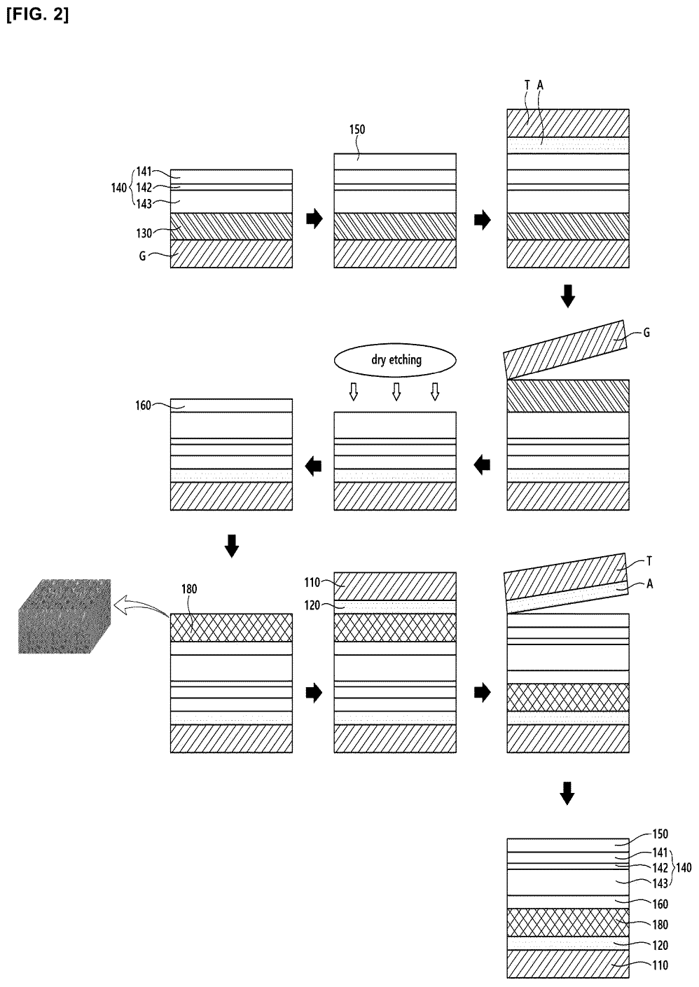

FIG. 1 is a flowchart of the method S100 of manufacturing a chip on carrier according to the first embodiment of the present disclosure, and FIG. 2 shows a process of manufacturing the chip on carrier according to the method S100 of manufacturing the chip on carrier according to the first embodiment of the present disclosure.

As shown in FIGS. 1 and 2, the method S100 of manufacturing the chip on carrier according to the first embodiment of the present disclosure is for manufacturing a micro LED chip element with a vertical chip structure, and includes operation S110 of sequentially forming an undoped semiconductor layer 130 and a light-emitting layer 140 on a growth substrate wafer G to manufacture an epitaxy wafer and forming a first ohmic contact electrode 150 on the epitaxy wafer, operation S120 of adhering the first ohmic contact electrode 150 to a temporary substrate wafer T through an adhesive layer A, operation S130 of removing the growth substrate wafer G to expose the undoped semiconductor layer 130, operation S140 of etching and removing the undoped semiconductor layer 130 to expose the light-emitting layer 140, operation S150 of forming a second ohmic contact electrode 160 on the light-emitting layer 140, operation S160 of forming a porous metal layer 180 on the second ohmic contact electrode 160, operation S170 of bonding the porous metal layer 180 to a support substrate wafer 110 through a bonding layer 120, and operation S180 of removing the temporary substrate wafer T and the adhesive layer A.

Meanwhile, as shown in FIG. 2, in the method S100 of manufacturing the chip on carrier according to the first embodiment of the present disclosure, a process may be performed at the wafer level without an etching process for a semiconductor region, and a process may also be performed at the chip level before forming a passivation layer or the like after performing the etching process on the semiconductor region to separate the semiconductor region in units of chip elements.

Operation S110 is an operation of sequentially forming the undoped semiconductor layer 130 and the light-emitting layer 140 on the initial growth substrate wafer G to manufacture the epitaxy wafer, and forming the first ohmic contact electrode 150 on the epitaxy wafer.

Here, the initial growth substrate wafer G is prepared as a sapphire substrate so that a high-quality light-emitting layer 140 may be grown, and the sapphire growth substrate wafer G is an optically transparent and high-temperature heat resistant substrate and may be prepared with α-phase Al2O3 sapphire (including ScAlMgO4) or the like. Further, it is also preferable that the initial growth substrate wafer G has a protrusion shape patterned regularly or irregularly in various dimensions (sizes and shapes) in micro-scale or nano-scale to minimize crystal defects such as dislocations or the like in a group 3 nitride light-emitting layer 140 thin film grown on top.

In operation S110, a group 3 nitride semiconductor is grown on the growth substrate wafer G, specifically, an epitaxy wafer sequentially grown in a micro-LED epitaxy structure composed of the undoped semiconductor layer 130 and the light-emitting layer 140 is manufactured in a metal organic chemical vapor deposition (MOCVD) chamber.

The undoped semiconductor layer is introduced to alleviate stress of the epitaxially grown light-emitting layer 140 and improve thin film quality before epitaxially growing the light-emitting layer 140 and serves as a buffer, and may be grown on the above-described growth substrate wafer G, and may be formed of, for example, unGaN, unInGaN, unAlGaN, or unAlGaInN, or the like.

The undoped semiconductor layer 130 may include a nucleation layer NL, and may be formed with a thickness of typically 2.5 μm to 3 μm. Further, when the growth substrate wafer G is removed using a laser lift off (LLO) technique, a sacrificial layer SL may be provided between the nucleation layer and the undoped semiconductor layer 130, and the nucleation layer may function as the sacrificial layer.

The light-emitting layer 140 generates light, and a binary, ternary, or quaternary compound such as InN, InGaN, GaN, AlGaN, AlN, or AlGaInN, or the like, which is a group 3 (Al, Ga, and In) nitride semiconductor among group 3 to 5 compound semiconductors, may be disposed in an appropriate position and order on the initial growth substrate wafer G and epitaxially grown. Specially, a high-quality group 3 nitride semiconductor such as InGaN having a high In composition should be preferentially formed on an upper portion (a multi-quantum well (MQW) region) of the group 3 nitride semiconductor composed of GaN, AlGaN, AlN, or AlGaInN, but is not limited thereto.

More specifically, the light-emitting layer 140 may include an n-type semiconductor layer 143, an active layer 142 of an MQW structure, and a p-type semiconductor layer 141.

The n-type semiconductor layer 143 has n-type conductivity and provides carrier electrons to the active layer 142, and may be grown on the undoped semiconductor layer 130. The n-type semiconductor layer 143 may have a thickness of 2.0 to 2.5 μm, and a lower surface may have a nitrogen polarity (an N-polarity), and may be formed of, for example, nGaN, nInGaN, nAlGaN, nAlGaInN, or the like.

The active layer 142 has an MQW structure and generates light using recombination of carrier electrons and holes, and may be grown on the n-type semiconductor layer 143. The active layer 142 may have a multi-layer structure and may have a thickness of about 50 nm.

The p-type semiconductor layer 141 has p-type conductivity and provides carrier holes to the active layer 142, and may be grown on the active layer 142. The p-type semiconductor layer 141 may have a multi-layer structure and may have a thickness of 0.5 μm or less, and an upper surface of the p-type semiconductor layer 141 may have a gallium polarity (a Ga-polarity), and may be formed of, for example, pGaN, pInGaN, pAlGaN, nAlGaInN, or the like.

Thereafter, in operation S110, the first ohmic contact electrode 150 may be formed on the p-type semiconductor layer 141, and in this case, the first ohmic contact electrode 150 may be formed as a p-type ohmic contact electrode.

Conventionally, since the stacked structure of a chip (a horizontal chip, flip chip, or the like) was completed using only the initial growth substrate wafer G, the p-type ohmic contact electrode had to be formed in a back-end process. In this case, since heat treatment should be essentially performed at a relatively high temperature of 400° C. to 750° C. to form the corresponding p-type ohmic contact electrode, there is a problem that the chip, in which a plurality of layers are already stacked, is damaged by the high temperature.

Accordingly, in the present disclosure, since the p-type ohmic contact electrode is formed through high-temperature heat treatment in a state in which other layers are not stacked (that is, in a state in which the structure of the chip is not completed) after growing the light-emitting layer 140, and then the remaining required layers are stacked, the problem of the stacked chip being damaged by the high-temperature heat treatment for forming the p-type ohmic contact electrode may be fundamentally prevented.

More specifically, in the present disclosure, the first ohmic contact electrode 150 is formed to be in contact with the p-type semiconductor layer 141 and is formed as a p-type ohmic contact electrode, and the first ohmic contact electrode 150 may be formed of a material such as NiO, PtO, PdO, AgO2, Au, Rh2O3, RuO2, In2O3, SnO2, ZnO, IZO, ITO, IGZO, or the like when formed of a material having transparent conductivity, and may be formed of a material such as Ag, Al, Au, Pt, Ni, Mo, Cu, Cr, Ti, or the like when formed of a material having reflectivity,.

Operation S120 is an operation of adhering the first ohmic contact electrode 150 to an intermediate temporary substrate wafer T through the adhesive layer A.

Here, it is preferable that the intermediate temporary substrate wafer T has a coefficient of thermal expansion (CTE) that is the same as or similar to those of the initial growth substrate wafer G and a final support substrate wafer 110, and when the intermediate temporary substrate wafer T is removed using a laser lift off (LLO) process, the intermediate temporary substrate wafer T may be formed of an optically transparent and high temperature heat-resistant sapphire (α-phase Al2O3) substrate through which a laser beam (single wavelength light) may be transmitted 100% (theoretically) without absorption, or glass whose coefficient of thermal expansion (CTE) is adjusted to have a difference of 2 ppm or less from that of the final support substrate wafer 110.

Further, the adhesive layer A may be formed of a metal or an alloy, a ceramic, or a resin material. Specifically, it is preferable to preferentially select a material which performs metallic bonding (eutectic bonding, diffusion bonding, direct bonding, or the like) as the adhesive layer A, and the adhesive layer A may include a material such as In, Sn, Ga, Zn, Au, Ag, Cu, Pd, Ni, Ti, Cr, Al, or Si as a metallic bonding material which may be soldered at a temperature of 300° C. or lower. Further, the adhesive layer A may include a material such as SiO2, a spin on glass (SOG) oxide, flowable oxides (FOx), SiNx, Al2O3, AlN, SiCN, ITO, IZO, ZnO, or the like as a ceramic material which may be directly bonded at a temperature of 100° C. or lower, and may also include a resin material such as epoxy, benzocyclobutene (BCB), polyimide (PI), or the like as an organic adhesive which may be indirectly bonded at a temperature of 100° C. or lower.

Meanwhile, in operation S120, a separation layer is formed on the intermediate temporary substrate wafer T, and then one side of the first ohmic contact electrode 150 may be adhered to the separation layer. The separation layer is a layer that is sacrificed and separated when the intermediate temporary substrate wafer T is removed, and a material such as SiO2, ZnO, ITO, a transparent conducting oxide (TCO), a transparent conducting nitride (TCN), or the like according to the LLO process may be used. Meanwhile, the separation layer may be located at the top or bottom of the adhesive layer A depending on the purpose, and when the adhesive layer A performs a function of the separation layer, the separation layer may be omitted.

Operation S130 is an operation of removing the initial growth substrate wafer G to expose the undoped semiconductor layer 130.

More specifically, in operation S130, the initial growth substrate wafer G may be removed using the LLO process, thereby exposing one side of the undoped semiconductor layer 130 to the outside. Here, the LLO process is a technique of separating epitaxially grown layers from the initial growth substrate wafer G by irradiating a back surface of the transparent initial growth substrate wafer G with an ultraviolet (UV) laser beam having uniform light output and beam profile, and a single wavelength. When the initial growth substrate wafer G is separated, the inside of the light-emitting layer 140 transferred to the intermediate temporary substrate wafer T is in a state in which the stress is completely relieved and maintains a flat state along with the intermediate temporary substrate wafer T.

Operation S140 is an operation of etching and removing the undoped semiconductor layer 130 to expose the light-emitting layer 140.

More specifically, in operation S140, the entire undoped semiconductor layer 130 with a thickness of 2.5 to 3 μm may be etched and removed using a dry etching process using a known gas (Cl2, BCl3, or Ar) plasma.

Operation S150 is an operation of forming the second ohmic contact electrode 160 on the exposed light-emitting layer 140. In this case, since the second ohmic contact electrode 160 is formed on the n-type semiconductor layer 143, the second ohmic contact electrode 160 may be formed as an n-type ohmic contact electrode.

The second ohmic contact electrode 160 may be formed of a material such as NiO, PtO, PdO, AgO2, Au, Rh2O3, RuO2, In2O3, SnO2, ZnO, IZO, ITO, IGZO, or the like when formed of a material having transparent conductivity, and the second ohmic contact electrode 160 may be formed of a material such as Ag, Al, Au, Pt, Ni, Mo, Cu, Cr, and Ti, or the like when formed of a material having reflectivity. Further, the second ohmic contact electrode 160 may be selectively heat-treated at a relatively low temperature in the range of 25 to 300° C., and may be formed after plasma treatment at an interface of the n-type semiconductor layer 143.

Operation S160 is an operation of forming the porous metal layer 180 on the second ohmic contact electrode 160.

When a vertical chip from which the undoped semiconductor layer 130 having a thickness of 2.5 to 3 μm is removed to form the n-type ohmic contact electrode is transferred to a panel for a conventional horizontal chip or flip chip, a step is generated by a thickness of the removed undoped semiconductor layer 130 and thus causes difficulty in subsequent processes, and thus there is a problem that it is difficult to manufacture normal products.

Accordingly, a method capable of forming the n-type ohmic contact electrode while compensating for a thickness of an element of the vertical chip is required, and to this end, in the present disclosure, the thickness of the element of the vertical chip may be compensated for by forming the porous metal layer 180 after removing the undoped semiconductor layer 130.

In this case, in the present disclosure, the porous metal layer 180 may be formed of nano porous gold (NPG).

More specifically, in operation S160, an alloy layer is formed by first alloying and depositing Au and Sn, or by alloying and depositing Au and Ag on the second ohmic contact electrode. In this case, in operation S160, a plurality of Au layers and Sn layers (or Ag layers) may be alternately stacked and then heat-treated to form the alloy layer. Here, a composition ratio of Au and Sn (or Ag) may be 7:3, but is not limited thereto.

Thereafter, in operation S160, the entire laminate including the alloy layer is dealloyed to form NPG having a porous structure by precipitating the entire laminate in a solution such as nitric acid and removing Sn or Ag.

Meanwhile, the above-described dealloying is not limited to operation S160 but may be performed in any operation after operation S160.

The porous metal layer 180 formed by the above-described NPG may compensate for the thickness of the element of the vertical chip and facilitate bonding of the vertical chip and the panel when the vertical chip is transferred to the panel.

Specifically, when the vertical chip is transferred to the panel, in the present disclosure, a bonding pad layer may be first formed on the panel using Ti, Cr, or the like, and then a bonding layer is formed on the bonding pad layer using Sn—Ag—Cu (SAC, may be classified into SAC-302, SAC-304, or the like depending on a composition ratio) including Sn which is a low melting point metal (a melting point of 230° C.), or a bonding material including In (a melting point of 173° C.). Thereafter, when the vertical chip is transferred so that the NPG porous metal layer 180 is located on the bonding layer, and then heat treatment is performed at a low temperature, the bonding material such as SAC in the bonding layer melts and penetrates into pores of the NPG porous metal layer 180, and accordingly, the vertical chip may be firmly and easily bonded to the panel, and since the bonding material does not spread in the horizontal direction, an electrical short circuit may be prevented.

Operation S170 is an operation of bonding the porous metal layer 180 to the support substrate wafer 110 through the bonding layer 120.

Here, the final support substrate wafer 110 is a substrate which supports the micro-LED epitaxy structure, and the final support substrate wafer 110 may be prepared as the sapphire (α-phase Al2O3) substrate or glass with an adjusted coefficient of thermal expansion (CTE).

Further, the bonding layer 120 may be formed of a ceramic, a resin, a metal or an alloy material. Specifically, it is preferable to preferentially select a ceramic or resin material as the bonding layer 120, and the bonding layer 120 may include a material such as SiO2, a spin on glass (SOG) oxide, flowable oxides (FOx), SiNx, Al2O3, AlN, SiCN, ITO, IZO, or ZnO, or the like as a ceramic material which may be directly bonded at a temperature of 100° C. or lower, and may also include a resin material such as epoxy, benzocyclobutene (BCB), polyimide (PI), or the like as an organic adhesive which may be indirectly bonded at a temperature of 100° C. or lower. Further, the bonding layer 120 may include a material such as In, Sn, Ga, Zn, Au, Ag, Cu, Pd, Ni, Ti, Cr, Al, Si, or the like as a metallic bonding material which may be soldered at a temperature of 300° C. or lower.

Meanwhile, in operation S170, a separation layer may be formed on the final support substrate wafer 110, and then one side of the porous metal layer 180 may be bonded to the separation layer. The separation layer is a layer that is sacrificed and separated when the final support substrate wafer 110 is removed, and a material such as SiO2, ZnO, ITO, a transparent conducting oxide (TCO), a transparent conducting nitride (TCN), or the like according to the LLO process may be used. Meanwhile, the separation layer may be located at the top or bottom of the bonding layer 120 depending on the purpose, and when the bonding layer 120 performs the function of the separation layer, the separation layer may be omitted.

Operation S180 is an operation of completing a structure of a chip on carrier 100 by removing the temporary substrate wafer T and the adhesive layer A.

More specifically, in operation S180, the intermediate temporary substrate wafer T is removed using the LLO process. When the intermediate temporary substrate wafer T is separated, the inside of the light-emitting layer 140 transferred to the final support substrate wafer 110 is in a state in which the stress is completely relieved and maintains a flat state along with the final support substrate wafer 110. Thereafter, in operation S180, the adhesive layer A is etched and removed, and when the separation layer is formed, the separation layer is also removed.

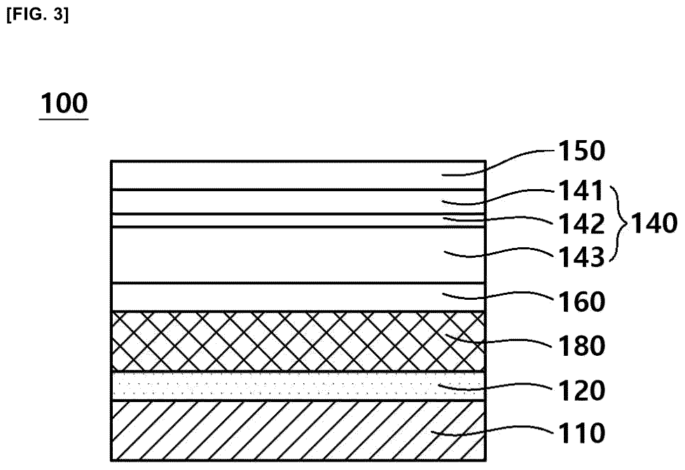

FIG. 3 shows the chip on carrier according to the first embodiment of the present disclosure in its entirety.

The chip on carrier 100 manufactured according to the method S100 of manufacturing the chip on carrier according to the first embodiment of the present disclosure as described above includes a support substrate wafer 110, a bonding layer 120 formed on the support substrate wafer 110, a porous metal layer 180 formed on the bonding layer 120, a second ohmic contact electrode 160 formed on the porous metal layer 180, a light-emitting layer 140 formed on the second ohmic contact electrode 160, and a first ohmic contact electrode 150 formed on the light-emitting layer 140.

Further, when a vertical chip is manufactured using the chip on carrier 100 according to the first embodiment of the present disclosure described above and then is transferred to a panel, a carrier substrate or the like is first attached to an upper portion of the first ohmic contact electrode 150, and then the support substrate wafer 110 and the bonding layer 120 are removed through laser lift-off to expose the porous metal layer 180. Thereafter, when the vertical chip is transferred so that the NPG porous metal layer 180 is located on the panel on which the bonding pad layer and the bonding layer are stacked, and then heat treatment is performed at a low temperature, the bonding material of the bonding layer melts and penetrates into the pores of the NPG porous metal layer 180, and accordingly, the vertical chip may be firmly and easily bonded to the panel. Meanwhile, since each configuration has been described above in the method S100 of manufacturing the chip on carrier according to the first embodiment of the present disclosure, overlapping descriptions will be omitted.

Hereinafter, with reference to the attached drawings, a method S200 of manufacturing a chip on carrier according to a second embodiment of the present disclosure will be described in detail.

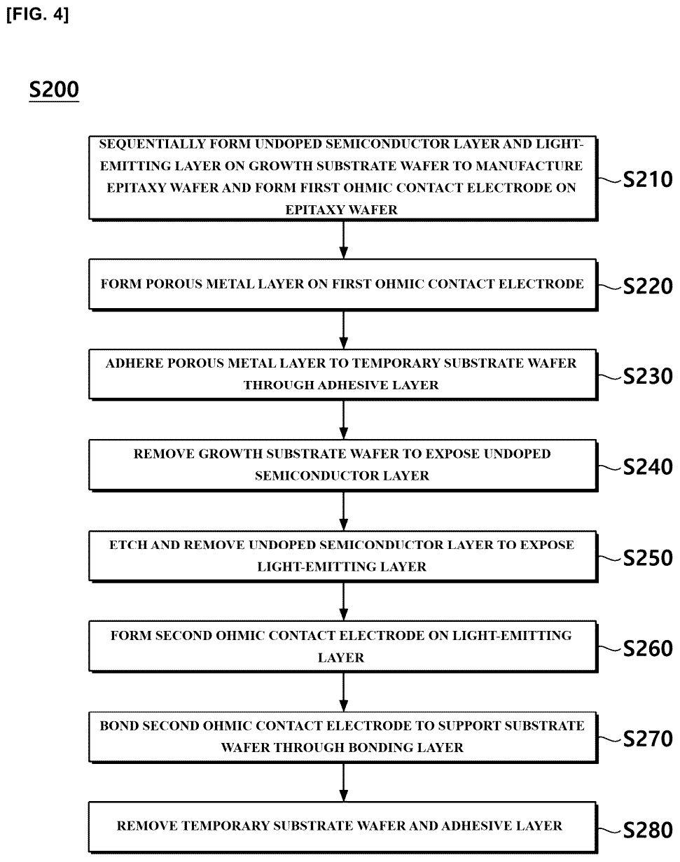

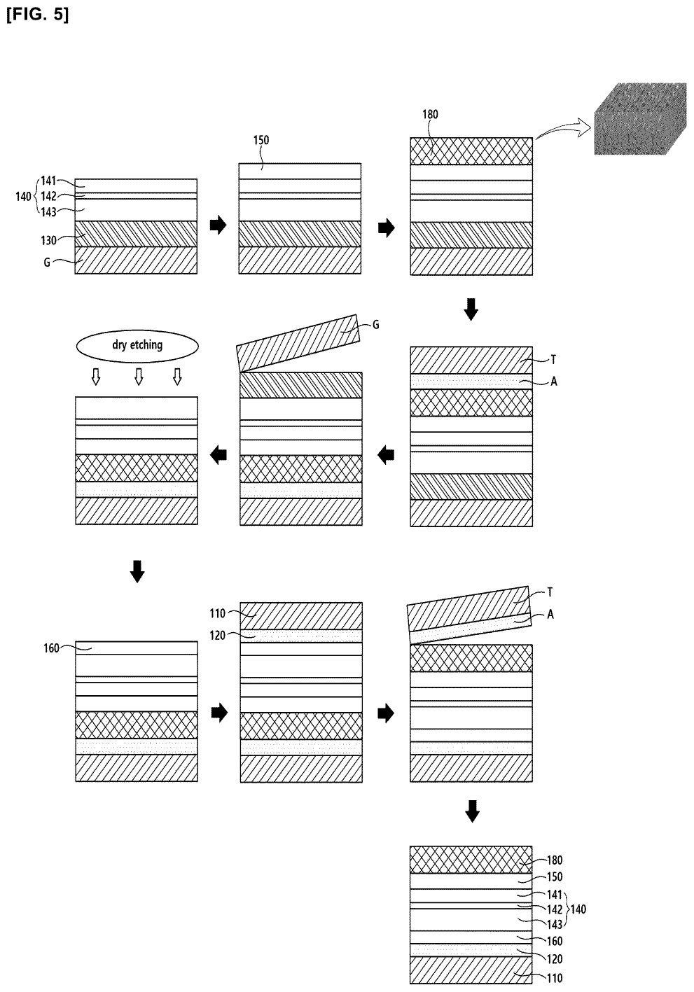

FIG. 4 is a flowchart of the method S200 of manufacturing the chip on carrier according to the second embodiment of the present disclosure, and FIG. 5 shows a process of manufacturing the chip on carrier according to the method S200 of manufacturing the chip on carrier according to the second embodiment of the present disclosure.

As shown in FIGS. 4 and 5, the method S200 of manufacturing the chip on carrier according to the second embodiment of the present disclosure is for manufacturing a micro LED chip element with a vertical chip structure includes operation S210 of sequentially forming an undoped semiconductor layer 130 and a light-emitting layer 140 on a growth substrate wafer G to manufacture an epitaxy wafer and forming a first ohmic contact electrode 150 on the epitaxy wafer, operation S220 of forming a porous metal layer 180 on the first ohmic contact electrode 150, operation S230 of adhering the porous metal layer 180 to a temporary substrate wafer T through an adhesive layer A, operation S240 of removing the growth substrate wafer G to expose the undoped semiconductor layer 130, operation S250 of etching and removing the undoped semiconductor layer 130 to expose the light-emitting layer 140, operation S260 of forming a second ohmic contact electrode 160 on the light-emitting layer 140, operation S270 of bonding the second ohmic contact electrode 160 to a support substrate wafer 110 through a bonding layer 120, and operation S280 of removing the temporary substrate wafer T and the adhesive layer A.

Meanwhile, as shown in FIG. 5, in the method S200 of manufacturing the chip on carrier according to the second embodiment of the present disclosure, a process may be performed at the wafer level without an etching process for a semiconductor region, and a process may also be performed at the chip level before forming a passivation layer or the like after performing the etching process on the semiconductor region to separate the semiconductor region in units of chip elements.

Operation S210 is an operation of sequentially forming the undoped semiconductor layer 130 and the light-emitting layer 140 on the initial growth substrate wafer G to manufacture the epitaxy wafer, and forming the first ohmic contact electrode 150 on the epitaxy wafer, and since operation S210 is the same as the above-described operation S110 of the method S100 of manufacturing the chip on carrier according to the first embodiment of the present disclosure, overlapping descriptions will be omitted.

Operation S220 is an operation of forming the porous metal layer 180 on the first ohmic contact electrode 150.

When a vertical chip from which the undoped semiconductor layer 130 having a thickness of 2.5 to 3 μm is removed to form the n-type ohmic contact electrode is transferred to a panel for a conventional horizontal chip or flip chip, a step is generated by a thickness of the removed undoped semiconductor layer 130 and thus causes difficulty in subsequent processes, and there is a problem that it is difficult to manufacture normal products.

Accordingly, a method capable of forming the n-type ohmic contact electrode while compensating for a thickness of an element of the vertical chip is required, and to this end, in the present disclosure, the thickness of the element of the vertical chip may be compensated for by removing the undoped semiconductor layer 130 after forming the porous metal layer 180.

In this case, in the present disclosure, the porous metal layer 180 may be formed of nano porous gold (NPG).

More specifically, in operation S220, an alloy layer is formed by first alloying and depositing Au and Sn on the second ohmic contact electrode, or by alloying and depositing Au and Ag. In this case, in operation S220, a plurality of Au layers and Sn layers (or Ag layers) may be alternately stacked and then heat-treated to form the alloy layer. Here, a composition ratio of Au and Sn (or Ag) may be 7:3, but is not limited thereto.

Thereafter, in operation S220, the entire laminate including the alloy layer is dealloyed to form NPG having a porous structure by precipitating the entire laminate in a solution such as nitric acid and removing Sn or Ag.

Meanwhile, the above-described dealloying is not limited to operation S220 but may be performed in any operation after operation S220.

The porous metal layer 180 formed by the above-described NPG may compensate for the thickness of the element of the vertical chip and facilitate bonding of the vertical chip and the panel when the vertical chip is transferred to the panel.

Specifically, when the vertical chip is transferred to the panel, in the present disclosure, a bonding pad layer may be first formed on the panel using Ti, Cr, or the like, and then a bonding layer is formed on the bonding pad layer using Sn—Ag—Cu (SAC, may be classified into SAC-302, SAC-304, or the like depending on a composition ratio) including Sn which is a low melting point metal (a melting point of 230° C.), or a bonding material including In (a melting point of 173° C.). Thereafter, when the vertical chip is transferred so that the NPG porous metal layer 180 is located on the bonding layer, and then heat treatment is performed at a low temperature, the bonding material such as SAC in the bonding layer melts and penetrates into pores of the NPG porous metal layer 180, and accordingly, the vertical chip may be firmly and easily bonded to the panel, and since the bonding material does not spread in the horizontal direction, an electrical short circuit may be prevented.

Operation S230 is an operation of adhering the porous metal layer to the temporary substrate wafer T through the adhesive layer A, and since the contents of the temporary substrate wafer T and the adhesive layer A are the same as the above-described operation S120 of the method S100 of manufacturing the chip on carrier according to the first embodiment of the present disclosure, overlapping descriptions will be omitted.

Further, operation S240 is an operation of removing the growth substrate wafer G to expose the undoped semiconductor layer 130, operation S250 is an operation of etching and removing the undoped semiconductor layer 130 to expose the light-emitting layer 140, and operation S260 is an operation of forming the second ohmic contact electrode 160 on the light-emitting layer 140, and since operations S240 to S260 are the same as the above-described operations S130 to S150 of the method S100 of manufacturing the chip on carrier according to the first embodiment of the present disclosure, overlapping descriptions will be omitted.

Further, since operation S270 is an operation of bonding the second ohmic contact electrode 160 to the support substrate wafer 110 through the bonding layer 120 and the contents of the support substrate wafer 110 and the bonding layer 120 are the same as the above-described operation S170 of the method S100 of manufacturing the chip on carrier according to the first embodiment of the present disclosure, and operation S280 is an operation of removing the temporary substrate wafer T and the adhesive layer A and is the same as operation S180 of the method S100 of manufacturing the chip on carrier according to the first embodiment of the present disclosure, overlapping descriptions will be omitted.

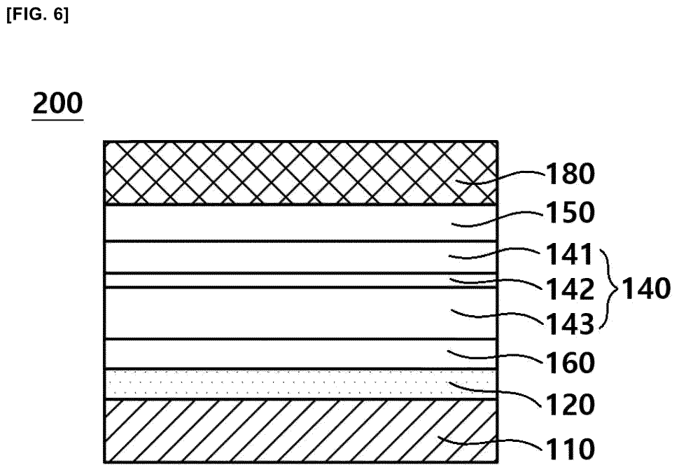

FIG. 6 shows the chip on carrier according to the second embodiment of the present disclosure in its entirety.

A chip on carrier 200 manufactured according to the above-described method S200 of manufacturing the chip on carrier according to the second embodiment of the present disclosure includes a support substrate wafer 110, a bonding layer 120 formed on the support substrate wafer 110, a second ohmic contact electrode 160 formed on the bonding layer 120, a light-emitting layer 140 formed on the second ohmic contact electrode 160, a first ohmic contact electrode 150 formed on the light-emitting layer 140, and a porous metal layer 180 formed on the first ohmic contact electrode 150.

Further, when a vertical chip is manufactured using the chip on carrier 200 according to the second embodiment of the present disclosure and then transferred to a panel, the vertical chip is first transferred using the support substrate wafer 110 as a carrier substrate so that the NPG porous metal layer 180 is located on the panel on which a bonding pad layer and a bonding layer are stacked, and then when heat treatment is performed at a low temperature, the bonding material of the bonding layer melts and penetrates into pores of the NPG porous metal layer 180, and accordingly, the vertical chip may be firmly and easily bonded to the panel. Meanwhile, since each configuration has been described above in the method S200 of manufacturing the chip on carrier according to the second embodiment of the present disclosure, overlapping descriptions will be omitted.

According to the above-described chip on carrier of the present disclosure and the method of manufacturing the same, since a thickness of an element of the vertical chip may be compensated for without lowering the performance or quality of the vertical chip, there is an effect that the vertical chip can be applied to a panel for conventional horizontal chip and flip-chip structures.

Further, according to the present disclosure, since the undoped semiconductor layer 130 is removed from the conventional vertical chip structure, there is an effect that the problem of an electrical short circuit occurring due to a thickness of the chip element becoming too thin can be prevented.

In addition, according to the present disclosure, since the bonding material penetrates into the pores of the porous metal layer 180, the vertical chip may be firmly and easily bonded to the panel, and since the bonding material does not spread in the horizontal direction, an electrical short circuit may be prevented.

Further, according to the present disclosure, there is an effect that the thickness of the element of the vertical chip can be freely adjusted through the porous metal layer 180.

According to the present disclosure, since a thickness of an element of a vertical chip can be compensated for without lowering the performance or quality of the vertical chip, there is an effect that the vertical chip can be applied to a micro light-emitting diode (LED) display panel using conventional horizontal chip and flip-chip structures.

Further, according to the present disclosure, since an undoped semiconductor layer is removed from a conventional vertical chip structure, there is an effect that the problem of an electrical short circuit occurring due to a thickness of the chip element becoming too thin can be prevented.

Further, according to the invention, since a bonding material penetrates into pores of a porous metal layer, the vertical chip can be firmly and easily bonded to the panel, and since the bonding material does not spread in a horizontal direction, an electrical short circuit can be prevented.

In addition, according to the present disclosure, there is an effect that the thickness of the element of the vertical chip can be freely adjusted through the porous metal layer.

Meanwhile, the effects of the present disclosure are not limited to the above-mentioned effects, and various effects can be included in the scope obvious to those skilled in the art from contents described above.

In the above, it is described that all the components constituting the embodiments of the present disclosure are combined or combined to operate as one, but the present disclosure is not necessarily limited to these embodiments. That is, within the scope of the present disclosure, one or more of all the components may be selectively combined to operate as one.

Further, the above-described term “include,” “compose,” “have,” or the like means that the corresponding component may be included unless specifically stated otherwise, and thus should be interpreted as including other components rather than excluding other components. All terms including technical or scientific terms have the same meaning that is generally understood by those in the art unless otherwise defined. Commonly used terms, such as terms defined in dictionaries should be interpreted according to their contextual meanings in the related art, and are not to be interpreted with ideal or excessively formal meanings unless explicitly defined in the present disclosure.

Further, the above description is merely an exemplary description of the technical spirit of the present disclosure, and those skilled in the art to which the present disclosure pertains will be able to modify and change the present disclosure in various ways without departing from the essential characteristics of the present disclosure.

Accordingly, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed according to the appended claims, and all technical ideas within the equivalent range should be construed as being included in the scope of the present disclosure.

What is claimed is:

1. A method of manufacturing a chip on carrier, comprising:
sequentially forming an undoped semiconductor layer and a light-emitting layer on a growth substrate wafer to manufacture an epitaxy wafer and forming a first ohmic contact electrode on the epitaxy wafer;
adhering the first ohmic contact electrode to a temporary substrate wafer through an adhesive layer;
removing the growth substrate wafer to expose the undoped semiconductor layer;
etching and removing the undoped semiconductor layer to expose the light-emitting layer;
forming a second ohmic contact electrode on the light-emitting layer;
forming a porous metal layer on the second ohmic contact electrode;
bonding the porous metal layer to the support substrate wafer through a bonding layer; and
removing the temporary substrate wafer and the adhesive layer.

2. The method of claim 1, wherein the porous metal layer is formed of nano porous gold (NPG).

3. The method of claim 1, wherein the light-emitting layer includes an n-type semiconductor layer, an active layer, and a p-type semiconductor layer.

4. The method of claim 1, wherein the support substrate wafer is formed of sapphire.

5. A chip on carrier comprising:
a support substrate wafer;
a bonding layer formed on the support substrate wafer;
a porous metal layer formed on the bonding layer;
a second ohmic contact electrode formed on the porous metal layer;
a light-emitting layer formed on the second ohmic contact electrode; and
a first ohmic contact electrode formed on the light-emitting layer.

6. A method of manufacturing a chip on carrier, comprising:
sequentially forming an undoped semiconductor layer and a light-emitting layer on a growth substrate wafer to manufacture an epitaxy wafer and forming a first ohmic contact electrode on the epitaxy wafer;
forming a porous metal layer on the first ohmic contact electrode;
adhering the porous metal layer to a temporary substrate wafer through an adhesive layer;
removing the growth substrate wafer to expose the undoped semiconductor layer;
etching and removing the undoped semiconductor layer to expose the light-emitting layer;
forming a second ohmic contact electrode on the light-emitting layer;
bonding the second ohmic contact electrode to the support substrate wafer through a bonding layer; and
removing the temporary substrate wafer and the adhesive layer.

7. The method of claim 6, wherein the porous metal layer is formed of nano porous gold (NPG).

8. The method of claim 6, wherein the light-emitting layer includes an n-type semiconductor layer, an active layer, and a p-type semiconductor layer.

9. The method of claim 6, wherein the support substrate wafer is formed of sapphire.
